(19) United States
(12) Patent Application Publication
(10) Pub. No.: US 2026/0363129 A1
(43) Pub. Date: Nov. 12, 2026

(54) DEVICE PACKAGE WITH HETEROGENEOUS DIE STRUCTURES AND METHODS OF FORMING SAME

(71) Applicant: Taiwan Semiconductor Manufacturing Co., Ltd., Hsinchu (TW)

(72) Inventors: Hung-Pin Chang, New Taipei City (TW); Wei-Cheng Wu, Hsinchu (TW); Der-Chyang Yeh, Hsinchu (TW)

(21) Appl. No.: 19/731,458

(22) Filed: Jul. 6, 2026

Related U.S. Application Data
(62) Division of application No. 18/506,747, filed on Nov. 10, 2023.
(60) Provisional application No. 63/508,328, filed on Jun. 15, 2023.

(51) Int. Cl. H10W 72/90; H10W 99/00; H10W 80/00; H10W 90/00

(52) U.S. Cl. CPC H10W 72/90; H10W 99/00; H10W 72/9445; H10W 72/952; H10W 80/312; H10W 80/327; H10W 90/792

(57) ABSTRACT

A package device includes a top die having a top interconnect structure on a first surface of a transistor layer and a bottom interconnect structure on a second surface of the transistor layer. One of the top interconnect structure or the bottom interconnect structure is direct bonded onto a bottom die. The bottom interconnect structure includes a power rail which directly contacts transistor contacts that are directly contacting a transistor structure in the transistor layer.

### PRIORITY CLAIM AND CROSS-REFERENCE

This application is a divisional of U.S. Patent Application No. 18/506,747, filed on Nov. 10, 2023, which claims the benefit of U.S. Provisional Application No. 63/508,328, filed on Jun. 15, 2023, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed. Further, as integrated circuit dies become increasingly complex and densely packed, new approaches to packaging such dies are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an exemplary package device, in accordance with some embodiments.

FIGS. 2 and 3 illustrate exemplary top die structures used in the package device of FIG. 1.

FIGS. 4A through 4F illustrate intermediate stages in an illustrative process for forming the exemplary top die structure of FIG. 2.

FIGS. 5A through 5H illustrate intermediate stages in an illustrative process for forming the exemplary top die structure of FIG. 3.

FIGS. 6A through 6H illustrate intermediate stages in an alternative illustrative process for forming the exemplary top die structure of FIG. 2.

FIGS. 7A through 7C are flowcharts illustrating salient steps of exemplary methods of forming illustrative package devices.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

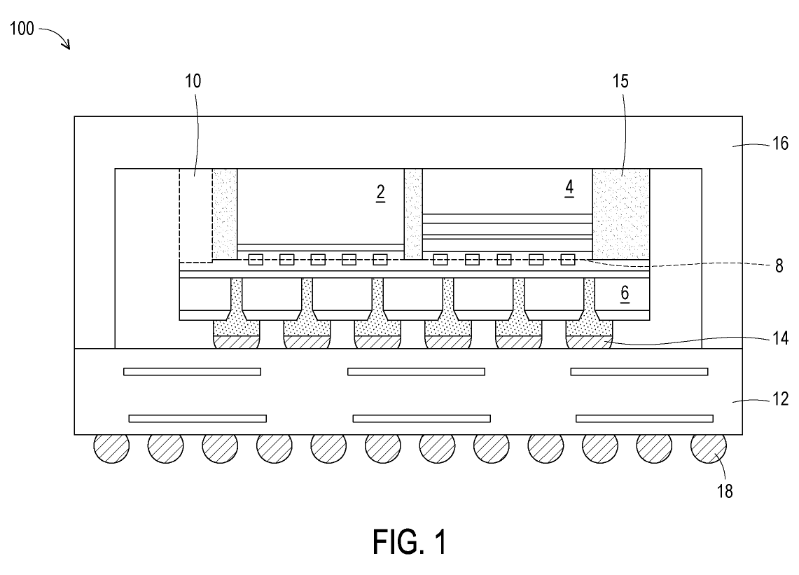

Turning now to FIG. 1, wherein an exemplary package device 100 is illustrated. The illustrative device 100 illustrates many advantageous features, some or all of which may be provided in the various embodiments described herein. In other words, not every feature illustrated in FIG. 1 is necessarily included in all contemplated embodiments. Some embodiments may have several features shown in FIG. 1, other embodiments will have different features shown in FIG. 1, and still other embodiments might include all of the illustrated features. Continuing with the description, package device 100 includes two top die, 2 and 4. Top die 2 and 4 are directed bonded onto bottom die 6, sometimes referred to herein as a bottom substrate. More specifically, top die 2 has an interconnect structure including contact pads embedded within and having respective top surfaces level with, a bonding dielectric layer. As indicated by bonding interface 8, the bonding dielectric layer of top die 2 is fusion bonded with a bonding dielectric layer on the top surface of bottom die 6 and likewise the contact pads embedded within the bonding dielectric layer of top die 2 are metal-to-metal bonded to corresponding contact pads embedded within the bonding dielectric layer on the top surface of bottom die 6. As also indicated by bonding interface 8, the bonding dielectric layer of top die 4 is fusion bonded with the bonding dielectric layer on the top surface of bottom die 6 and likewise the contact pads embedded within the bonding dielectric layer of top die 4 are metal-to-metal bonded to corresponding contact pads embedded within the bonding dielectric layer on the top surface of bottom die 6. Further details about the top die and the bonding process will be provided in the following descriptions of the figures.

As but one advantageous feature of illustrative package device 100, the disclosed structure allows for great flexibility in forming package devices with different configurations. For instance, top die 2 and top die 4 could be formed with different technology nodes / processes for heterogeneous integration. As but one example, top die 2 could be formed using a planar transistor technology node, a FinFET technology node, or the like, whereas top die 4 could be formed using, e.g., a stacked nanostructure technology node, as will be described in greater detail below. In some contemplated embodiments, top die 4 could incorporate a combination of technology nodes, such as FinFET transistors in combination with stacked nanostructure transistors, for instance. As another example of manufacturing flexibility, top die 2 could be bonded to bottom die 6 using contact pads having a first pitch (i.e., center to center spacing), while top die 4 is bonded to bottom die 6 using contact pads having a second pitch different than the first pitch. In yet other embodiments, manufacturing flexibility can be increased by allowing for different redistribution schemes. For instance, in some contemplated embodiments, one of top die 2 or top die 4 could be manufactured with aluminum contact pads, whereas the other of the top die 2 or top die 4 could be manufactured with a redistribution structure, sometimes referred to herein as an interconnect structure having copper contact pads. Both types of redistribution schemes are accommodated by package device 100, as described more fully below.

Continuing with the description of exemplary package device 100, bottom die 6 may, in some embodiments, be connected to a package substrate 12, such as a printed circuit board, an interposer, a carrier substrate, a coreless substrate, or the like, through connectors 14. One skilled in the art will recognize connectors 14 could be implemented through numerous approaches such as solder balls, solder pads or bumps, controlled collapse chip connection (C4) technology, copper pillars, or the like. Similarly, package substrate 12 could be further connected to other package components or to external components through external connectors 18.

In some embodiments, top die 2 and/or top die 4 are encapsulated in an encapsulant 15, which could be molding compound, underfill material, a polymer material, or the like, and combinations of same. FIG. 1 also illustrates a dummy die 10 which may be included in some embodiments in order to provide a more topographically uniform profile when applying encapsulant 15, to provide heat sinking mass, to help support top die 2 and/or top die 4 during manufacturing processes, to compensate for coefficient of thermal expansion (CTE) mismatch of components of package device 100, and the like. Finally, FIG. 1 illustrates a lid 16 that includes a top and sides, which lid may be included in some embodiments to provide for thermal management, mechanical protection, water and/or dust protection, and the like, as is known in the art.

One skilled in the art will recognize that FIG. 1 is highly simplified for clarity and ease of reference, and that in actual practice many top die 2 and 4 could be included in package device 100. Likewise, only a few contact pads between the respective top die 2, 4 and bottom die 6 are illustrated, as are only a few exemplary connectors 14 and external connectors 18 illustrated – whereas in actual product, scores if not hundreds of such connectors and contact pads would be used to make electrical connection between the various components of package device 100.

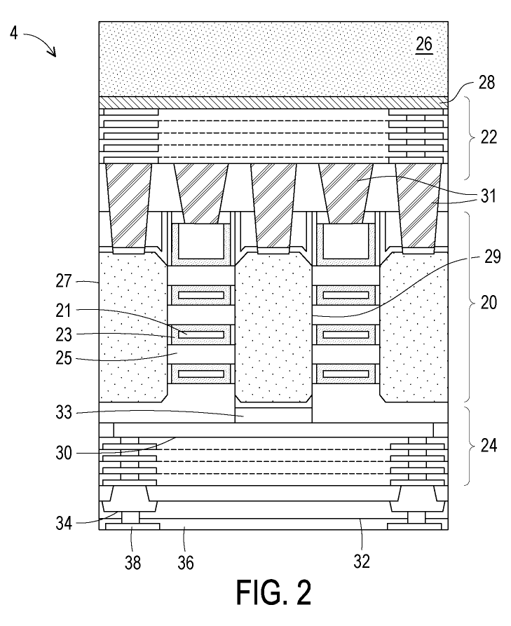

Turning now to FIG. 2, further exemplary details regarding illustrative top die 4 are shown. Top die 4 can be logically broken down into three main regions. In the center is a logic region sometimes referred to herein as a transistor layer 20. In the illustrated embodiment the transistors formed in transistor layer 20 are stacked nanostructure transistors having a stack of channel regions 21 (formed of a semiconductor material), each channel region of the stack being surrounded by a gate dielectric 23 and a gate electrode 25. Source region 27 and drain region 29 are formed adjacent to each channel region (with drain region 29 being shared between two transistors in the illustrated embodiment). Top die 4 also includes a frontside interconnect structure 22 formed on a top side (sometimes referred to herein as a top surface) of transistor layer 20 and a backside interconnect structure 24 formed on a bottom side (sometimes referred to herein as a bottom surface) of transistor layer 20. The terms “top” and “bottom” in this context are arbitrary, as the device could easily be turned in a different vertical orientation (and in fact, is done so during the manufacturing process of some embodiments, as described below). As used herein, the terms “top” and “bottom” are not intended to suggest a mandatory orientation, but rather are used as convenient terms to comport with the orientation shown in FIG. 1, for instance, and for the sake of a common point of reference by which to consistently distinguish one side of transistor layer 20 from the other side of transistor layer 20.

FIG. 2 illustrates a few advantageous features of top die 4 that are contemplated in the illustrated embodiments. First, it should be noted that top die 4 does not include a bulk substrate or bulk wafer, as is commonly found with integrated circuits. This will be explained in greater detail below with regard to the description of preferred manufacturing processes for forming embodiments of top die 4. Additionally, and as a consequence of the first feature, transistor contacts 31 and 33 can be formed directly contacting the transistors in transistor layer 20 from both the “top” of the transistor (in the case of transistor contacts 31) and the “bottom” of the transistor (in the case of transistor contact 33). In the illustrated embodiment, transistor contact 33 (formed in the backside interconnect structure 24) directly electrically contacts shared source / drain region 29 of the transistors, and transistor contacts 31 (formed in the frontside interconnect structure 22) directly gate electrodes 25 and/or contact source / drain regions 27 / 29. Because this architecture allow for contacting transistors from both the top and the bottom, enhanced flexibility in the routing and design on interconnects is achieved.

Another consequence of the absence of a bulk substrate or wafer is that the device does not have structural integrity and would easily be damaged, e.g., by handling, subsequent processing, and the like. For this reason, a support substrate 26 is employed. After frontside interconnect structure 22 is formed (e.g., by depositing a series of dielectric layers in a stack and forming within each such dielectric layer a pattern of conductive elements such as wires, pads, and conductive vias, using processes such as electroplating, electro-less plating, damascene processes, and the like, as is generally known in the art) support substrate 26 is bonded on the top of frontside interconnect structure 22, e.g. using an adhesive or bonding layer 28. Once support substrate 26 is bonded to the device, the bulk wafer in which transistor layer 20 is originally formed can be removed, as described in more detail below. As a consequence of support substrate 26 being bonded onto frontside interconnect structure 22, frontside interconnect structure 22 preferably provides only intra-chip connections, i.e. electrical connections between the various transistors and other components formed in and/or on top die 4, but preferably does not provide electrical connections to external components, i.e., components that are not formed in top die 4.

Fortunately, backside interconnect structure 24 is not encumbered with a support structure and hence can be employed to provide for electrical connections (signals and power) to / from external components. For this reason, power rail 30, sometimes also referred to as a backside power line, backside power rail, super power rail, or the like is advantageous. Using backside interconnect structure 24 and backside contacts 33, power can be easily and efficiently routed to components in transistor layer 20, such as the illustrated stacked nanostructure transistors, by power rail 30. FIG. 2 also illustrates passivation layer 32 formed at the outermost surface of backside interconnect structure 24 and landing pads 34 formed therein. In a conventional structure, landing pads 34 are typically formed of aluminum and serve as a land upon which to form connectors such as solder balls, solder bumps or the like to electrically connect top die 4 to other package components. By contrast, in the illustrated embodiment, bonding layer 36 is formed over passivation layer 32 and contact pads 38 are embedded within bonding layer 36, with respective top surfaces of respective contact pads 38 being level with the top surface of bonding layer 36. In this way, both bonding pads 38 and bonding layer 36 can make contact with and bond to respective bonding pads and bonding layer of bottom die 6 during a bonding process, as will be described in greater detail below. Preferably then, contact pads 38, which are sometimes referred to herein as bonding pads, are formed of copper or a copper alloy (to promote strong bonding with the contact pads of bottom die 6).

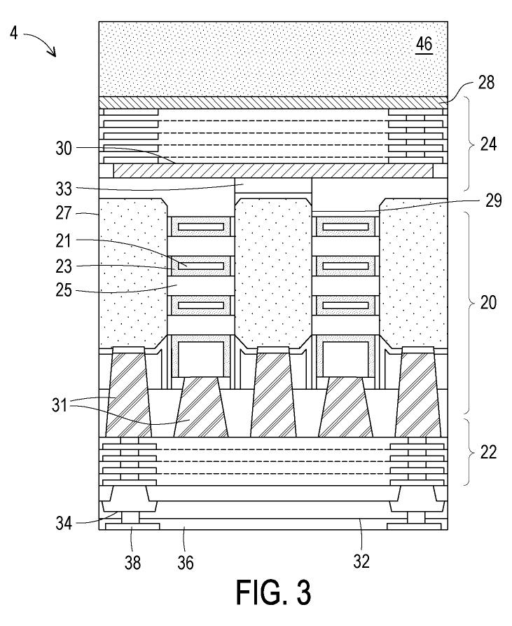

FIG. 3 illustrates another embodiment top die 4. In this embodiment, frontside interconnect structure 22 is bonded to bottom die 6 (as opposed to backside interconnect structure 24 being bonded per the embodiment illustrated in FIG. 2). With the exception that frontside interconnect structure 22 is now shown on the bottom of the figure and the backside interconnect structure is now shown at the top of the figure, the components illustrated in FIG. 3 are essentially the same as those illustrated in FIG. 2, as indicated by the like reference numerals being employed. Another key difference between the embodiments is that in FIG. 3, a support substrate, in this case support substrate 46, is bonded to backside interconnect structure 24 (rather than to frontside interconnect structure 22, as was the case in the embodiment shown in FIG. 2). This type of embodiment requires different treatment of support substrate 26, as will be described in greater detail below.

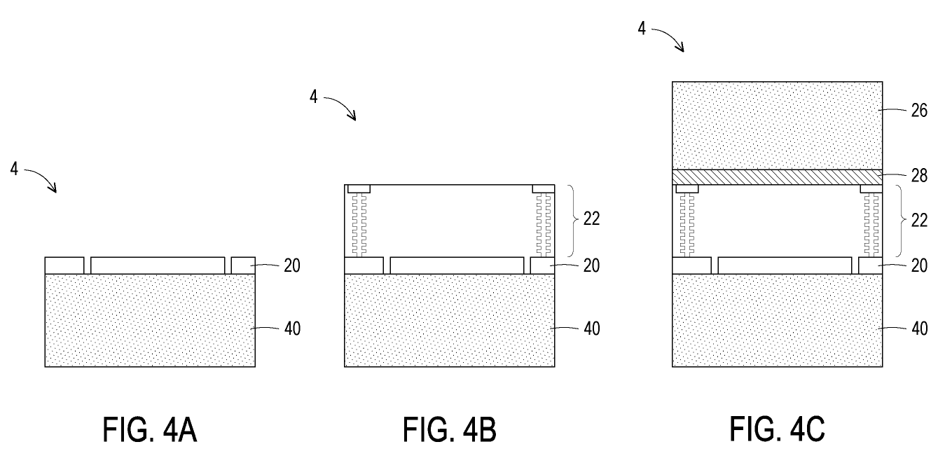

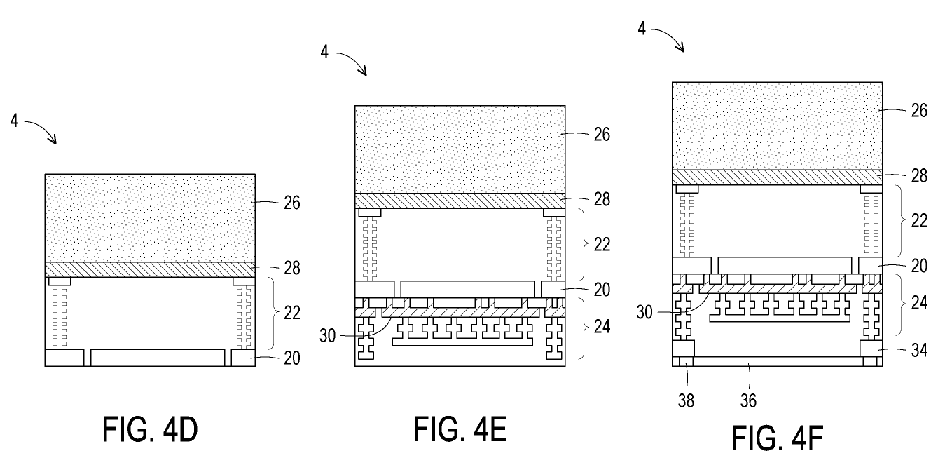

An illustrative process for forming the package device illustrated in FIG. 2 will now be described with regard to FIGS. 4A through 4F, which illustrate various intermediate stages in one embodiment process flow. Starting with FIG. 4A, in this stage transistor layer 20 has been formed on (and in some cases at least partially in) a bulk wafer 40. The details for forming transistors in transistor layer 20 are not necessary for an understanding of the present disclosure and the advantages and applications of the package device embodiments disclosed herein. For context, however, salient steps in the formation of transistor layer 20 include (but are not limited to), forming a stack of alternating layers of first semiconductor material and second semiconductor material on bulk wafer 40. The stack of alternating layers can be patterned to form respective columns. Two such columns of alternating layers, illustrated after a step of removing the layers of first semiconductor material from the respective columns, are illustrated in FIG. 2, discussed above. Source and drain regions can be epitaxially grown adjacent respective columns, using processes that are within the purview of those skilled in the art once informed by the present disclosure. The step of removing the layers of first semiconductor material leaves a stack of regions of second semiconductor material with gaps therebetween. These regions of second semiconductor material form the channel regions of transistors that are formed in transistor layer 20. This is accomplished by depositing a dielectric material surrounding the respective channel regions, and then forming a gate electrode around the dielectric material. While stacked nanostructure transistors are shown in the exemplary embodiments, other transistor structures, including FinFETs, stacked FET structures, and the like are within the scope of this disclosure and could readily be incorporated into the process flows and structures illustrated herein by one skilled in the art using routine experimentation once informed by the present disclosure.

Continuing with FIG. 4B, the stage of manufacture in which frontside interconnect structure 22 has been formed is illustrated. Those skilled in the art will recognize numerous processes and techniques for forming an interconnect structure, preferably comprising a stack of patterned conductive layers embedded with respective layers of a stack of dielectric layers, the conductive layers being electrically interconnected by conductive vias vertically extending through respective dielectric layers between adjacent conductive layers. In some embodiments, a patterned conductive layer is first formed, and then embedded within a dielectric layer that is deposited over it, which is then patterned to allow for subsequent electrical contact to the conductive layer – which steps are repeated to form a stack of such layers. In other embodiments, by contrast, a damascene process may be employed in which a dielectric layer is first formed and then patterned to provide trenches and holes therein, which trenches and holes are subsequently filled with a conductor such as copper or a copper alloy to form wires and conductive vias, respectively – which process is then repeated to form a stack of metallization layers.

In FIG. 4C, support substrate 26 is bonded to a top surface of frontside interconnect structure. Support substrate 26 is selected based upon one or more properties such as coefficient of thermal expansion (CTE), mechanical rigidity, thermal conductance, brittleness, hardness, compatibility with existing packaging technologies, cost, ease of handling, and the like. For many contemplated embodiments, a silicon wafer is a suitable candidate for support substrate 26. In other contemplated embodiments, a quartz substrate or other material may be preferable, depending upon the specific demands of the application. In the illustrated embodiment, bonding layer 28, such as an adhesive layer, is employed for bonding support structure 26 to frontside interconnect structure 22. Those skilled in the art will recognize numerous alternative materials that could be employed as bonding layer 28 using routine experimentation once informed by the present disclosure. In yet other embodiments, bonding layer 28 could be eliminated altogether assuming that the surface of frontside interconnect structure 22 and the surface of support structure 26 have properties allowing them to be directly bonded together with sufficient bond strength. As but one example, assuming that both frontside interconnect structure 22 and support substrate 26 both have a sufficiently smooth and planar silicon dioxide bonding surface, either untreated or having been treated with, e.g., a plasma treatment, then it is likely that frontside interconnect structure 22 and support substrate 26 could be bonded together without the need of bonding layer 28 and without the need of excessive heat and/or pressure being applied to adequately bond the components together.

After support substrate 26 has been attached, processing can continue with removing bulk wafer 4, as shown in FIG. 4D. This can be accomplished using known techniques such as grinding away the backside of bulk wafer 4, chemically etching back the backside of bulk wafer 4, or a combination of both grinding and etching (e.g., gross grinding operation to remove most of bulk wafer 4 followed by a fine etch process to ensure the protection of transistor layer 20 during the final phase of removal of bulk wafer 4). Other techniques for thinning bulk wafer 4, both currently known and to be developed, are within the contemplated scope of applications of the present disclosure. In the illustrated embodiment, bulk wafer 4 has been completely removed, leaving the bottom surface of transistor layer 20 completely exposed. In other contemplated embodiments, residual portions of bulk wafer 4 may remain (not illustrated). Residual portions is intended to encompass discontinuous regions of remnants of bulk wafer 4 remaining on one or more portions of the surface of transistor layer 20, as well as encompassing a continuous, although significantly thinned, layer of bulk substrate 4 remaining on the entire or a substantial portion of the surface of transistor layer 20. Hence, as used herein and unless expressly stated otherwise or unless the context in which the term is used requires otherwise, the phrases “remove” bulk wafer, “removing” bulk wafer, and the like, are is intended to include a complete removal of all vestiges of the bulk wafer as well as to include a less than complete removal of the bulk wafer in which case residual portions or a residual layer of bulk wafer 4 remains after the removal process. For further guidance, the terms remove, removing, etc. of bulk wafer 4 are intended to encompass a process in which bulk wafer 4 no longer significantly mechanically supports transistor layer 20 after the removal process, even if some portion or portions of bulk wafer 4 remain after the process.

After bulk wafer 4 is removed, processing continues with the formation of backside interconnect structure 24, as illustrated in FIG. 4E. In this illustrated embodiment, backside interconnect structure 24 comprises a stack of dielectric layers in which are formed respective conductive layers. Backside interconnect structure 24, like frontside interconnect structure 22, could be formed using conventional back-end-of-line (BEOL) processes employed in conventional CMOS manufacturing techniques, including the above-described processes for forming frontside interconnect structure 22. While it is contemplated that the same or similar processes and materials would be used in forming both frontside interconnect structure 22 and backside interconnect structure 24, this is not a requirement of the present disclosure and this disclosure accommodates a wide range of different manufacturing processes for the interconnect structures described herein. For instance, backside interconnect structure 24 as illustrated in FIG. 4F has a top conductive layer having aluminum landing pads 34, as are commonly employed in CMOS manufacturing processes. The use of copper bonding pads 38 formed on landing pads 34, ensures that top die 4 can be direct bonded to bottom die 6 regardless of the BEOL process used in forming the interconnect structure.

A particularly advantageous feature of the embodiment illustrated in FIGS. 4A through 4F is the presence of power rail 30 in backside interconnect structure 24. As addressed above, power rail 30 directly contacts transistor contacts 33 in transistor layer 20 (illustrated in FIGS. 2 and 3), providing for a low resistance path for transmitting power to the transistors and related circuitry in transistor layer 20. Power rail 30 is preferably, although not necessarily, formed of a thicker and/or wider conductor, relative to other signal-carrying conductors in backside interconnect structure 24, to ensure a low resistance path. One skilled in the art will recognize that power rail 30 is formed in only a single layer of backside interconnect structure 24 in the illustrated embodiment. While such an architecture should suffice for most, if not all, applications, embodiments in which two or more layers of backside interconnect structure 24 include a power rail 30 are within the contemplated scope of the present disclosure.

In a next step, top die 4 is directly bonded to bottom die 6, preferably by fusion bonding passivation layer 36, sometimes also referred to herein as bonding layer 35, to a corresponding dielectric bonding layer of bottom die 6 (illustrated in FIG. 1) and by metal-to-metal bonding pads 38 to corresponding bonding pads on bottom die 6 (illustrated in FIG. 1). Subsequent processes such as bonding one or more top die 2 to bottom die 6, forming dummy dies 10, encapsulating top die 2 and/or top die 4, and/or dummy die(s) 10 in encapsulant 15, forming lid 16, and the like are performed next, but are not illustrated as the details of same are not necessary in order to fully understand the present disclosure.

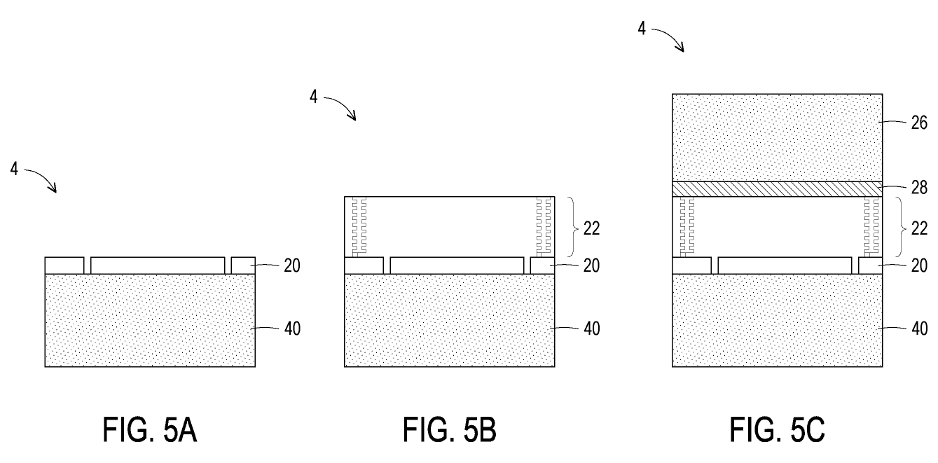

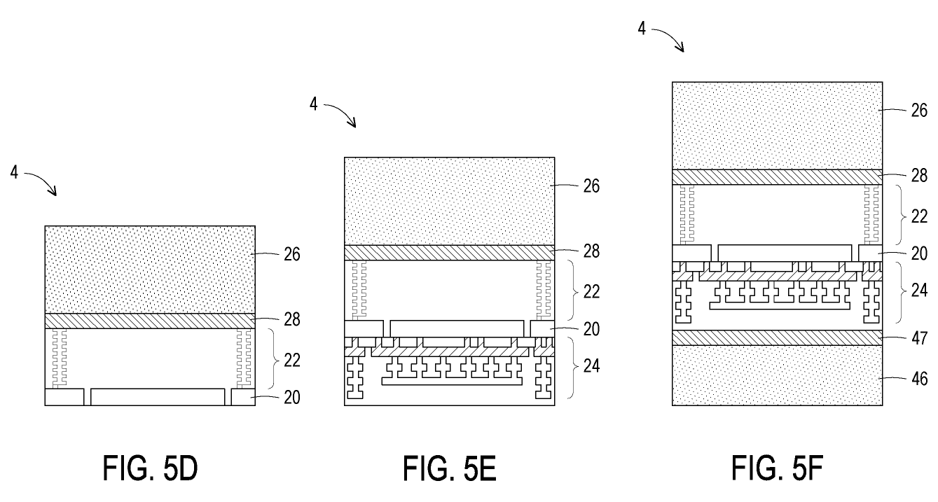

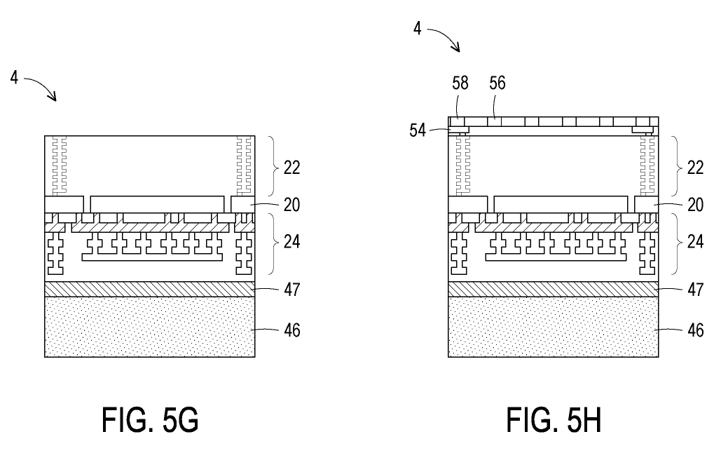

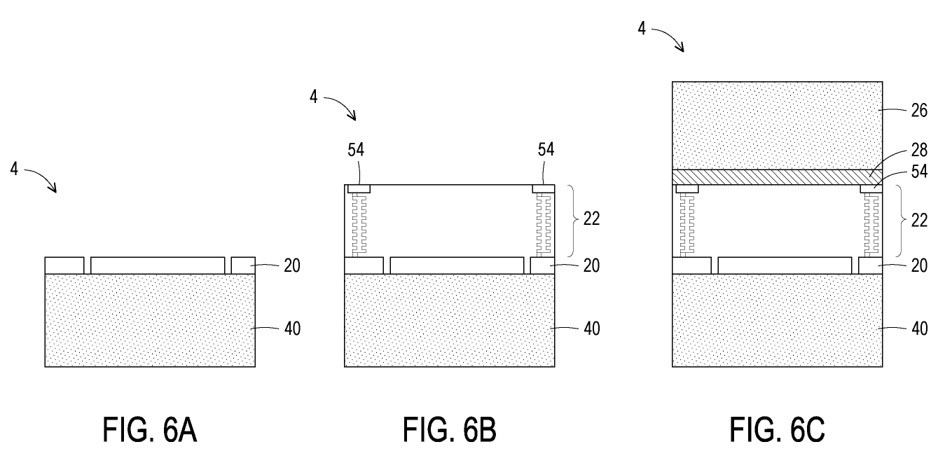

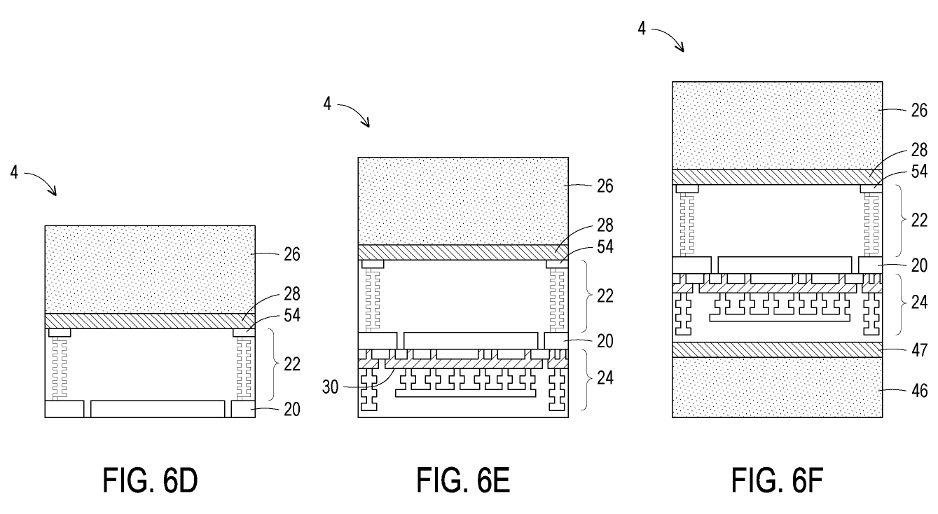

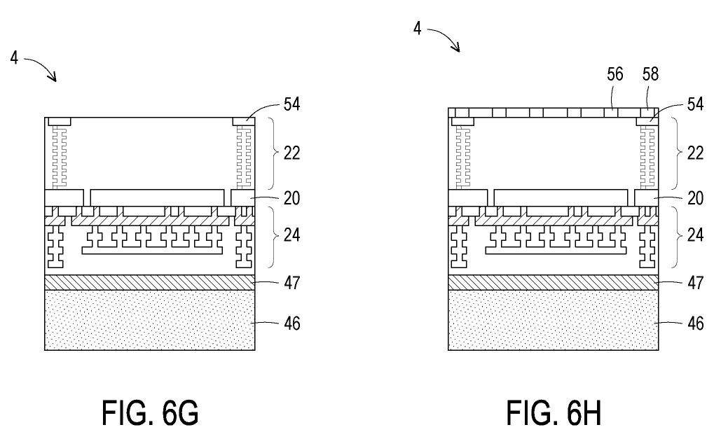

FIGS. 4A through 4F illustrated steps in an exemplary process for forming the illustrative top die 4 used in the embodiment structure illustrated in FIG. 2, wherein top die 4 is bonded to bottom die 6 through backside interconnect structure 24. Returning attention to the embodiment structure illustrated in FIG. 3, wherein top die 4 is bonded to bottom die 6 through frontside interconnect structure 24, FIGS. 5A through 5G illustrate steps in an exemplary process for forming the illustrative top die 4 used in the embodiment structure illustrated in FIG. 2, and FIGS. 6A through 6G illustrate an alternative exemplary process for forming the illustrative top die 4 used in the embodiment structure illustrated in FIG. 2.

Beginning with FIG. 5A, this figure illustrates a same stage of manufacture as was illustrated and described above with respect to FIG. 4A. In this stage, transistor layer 20 has been formed at a top surface of bulk wafer 40, as described above. Similarly, FIGS. 5B, 5C, 5D, and FIG. 5E correspond to the same stages and process steps as were illustrated and described with respect to FIGS. 4B, 4C, 4D, and FIG. 4E, respectively, wherein frontside interconnect 22 is formed, support substrate 26 is mounted, and bulk wafer 40 is removed, and (at least part of) backside interconnect structure 24 is formed, respectively.

The processes diverge starting with FIG. 5F. In this process flow, support structure 26 must be removed in order to allow for bonding to frontside interconnect structure 22. This is shown in FIG. 5F, which illustrates top die 4 after second support substrate 46 has been bonded to bottom interconnect structure 24, such as with an adhesive layer 47. Then, as shown in FIG. 5G, support structure 26 is removed. In this embodiment, bond layer 28 used to bond support structure 26 should be selected to allow for removal of support structure 26 without damaging underlying frontside interconnect structure 22. For instance, in some embodiments, bonding layer 28 is a material that loses its adhesive properties when exposed to certain wavelengths of radiation and support substrate 26 is functionally transparent to those certain wavelengths of radiation. In other embodiments, bonding layer 28 is susceptible to chemical attack, such as by a solvent that removes or degrades bonding layer 28 without attacking or otherwise damaging the other components of top die 4. Various techniques for removing support substrate 26 will be apparent to those skilled in the art once informed by the present disclosure.

Processing continues as illustrated in FIG. 5H, with bond pads 58 having been formed on landing pads 54 and embedded within bonding layer 56. As an example, bond pads 58 and bonding layer 56 could be the same or similar materials formed in the same or a similar manner as are bond pads 38 and bonding layer 36 discussed above with reference to FIG. 4F. One should note that the orientation of top die 4 in FIGS. 5A – 5G is with frontside interconnect structure 22 shown on top for consistency with other figures. In practice, top die 4 would be flipped prior to bonding so that bond pads 58, bonding layer 56 pointing “down” so as to make contact with bottom die 6, as shown in FIG. 3. Next, frontside interconnect structure 22 is bonded onto bottom die 6, as shown in FIG. 1 – in this case bond pads 38 form metal-to-metal bonds with corresponding bond pads on bottom die 6 and bonding layer 56 forms a fusion bond, a dielectric-to-dielectric bond, or the like with a corresponding dielectric layer of bottom die 6. After top die 4 is bonded to bottom die 6, support substrate 46 can be removed, or alternatively can be patterned in order to allow for electrical connection to backside interconnect structure 24 and hence to power rail 30.

Yet another process for forming the illustrative top die 4 used in the embodiment structure illustrated in FIG. 3, is shown in FIGS. 6A through 6G. Most of the steps illustrated in FIGS. 6A through 6H have already been described with regard to FIGS. 5A through 5H, respectively. The difference between these process flows is best seen by a comparison of FIGS. 5B and 6B. Whereas in FIG. 5B, frontside interconnect structure 22 has only conductive interconnect layers, in FIG. 6B topside interconnect structure 22 has conductive interconnect layers and also has formed therein landing pads 54. By contrast, landing pads 54 are not formed until the process step illustrated in FIG. 5H for the previously described process flow. Other than this distinction, the process flows for FIGS. 5A through 5H and FIGS. 6A through 5H are substantially the same, and hence a detailed description of FIGS. 6A through 6H is omitted for the sake of brevity. As with the previously described embodiments, processing continues with mounting top die 4 onto bottom die 6 by a direct bonding process, mounting other dies such as top die 2 onto bottom die 6, adding dummy die 10 if appropriate, encapsulating with encapsulant 15, and/or enclosing within lid 16.

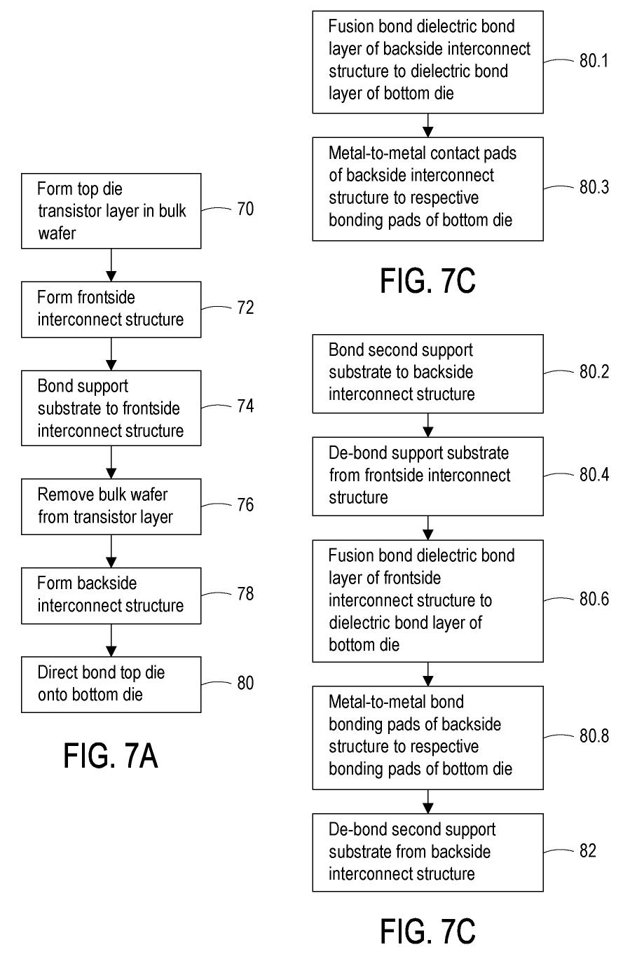

Turning now to FIGS. 7A through 7C, exemplary processes for forming a package device are illustrated in the form of flow charts. Step 70 of FIG. 7A represents the process of forming a transistor layer, such as transistor layer 20 illustrated in FIG. 2. This step includes forming transistors and support structures in a bulk wafer. Next step 72 represents forming a front side interconnect structure over the transistor layer whereby transistors and other passive and active devices in the top transistor can be interconnected. Frontside interconnect structure 22 illustrated in FIG. 2 is an example of a frontside interconnect structure formed by step 72. In step 74, a support substrate, such as support substrate 26 described above, is bonded to the frontside interconnect structure. Step 76 represents a process for removing the bulk wafer from the transistor layer, such as was described above with reference to FIG. 4D. In a next process, represented as step 78 in the process flow of FIG. 7A, a backside interconnect structure, such as backside interconnect structure of FIG. 2, for example, is formed over the backside of the transistor layer. Next, as represented by step 80 in the process flow of FIG. 7A, the top die, comprising the transistor layer, the frontside interconnect structure, and the backside interconnect structure, is direct bonded to a bottom die, such as for example bottom die 6 of FIG. 1.

FIG. 7B is a flow chart illustrating sub-steps 80.1 and 80.3 that fall within the larger step 80 illustrated in FIG. 7A for some of the embodiments disclosed herein. Step 80.1 represents a process of fusion bonding a dielectric bond layer of the backside interconnect structure to a dielectric bond layer of the bottom die, such as illustrated in FIG. 1 (as indicated by interface 8). Step 80.3 represents a process, ideally performed simultaneously with the process represented by step 80.1, of metal-to-metal bonding bonding pads of the backside interconnect structure to respective bonding pads of the bottom die. An example of these process sub-steps is provided above with respect to the embodiment illustrated in FIG. 4F.

FIG. 7C is a flow chart illustrating sub-steps 80.2 through 80.8 and 82 that fall within the larger step 80 illustrated in FIG. 7A for others of the embodiments disclosed herein. Step 80.2 represents a process of bonding a second support substrate to the backside interconnect structure, and step 80.4 represents a process of de-bonding the first support substrate (see step 74) from the frontside interconnect structure. In these embodiments, such as illustrated by FIGS. 4A through 4F, a bond dielectric bond layer of the frontside interconnect structure to is fusion bonded to a dielectric bond layer of the bottom die (represented by step 80.6), and bonding pads of the backside structure are metal-to-metal bonded to respective bond pads of the bottom die (represented by step 80.8). In an optional next process, the second support substrate may be de-bonded from the backside interconnect structure, as represented by step 82. This de-bonding allows for making electrical contact the transistor layer through the backside interconnect structure, including any power rails included therein.

While the present disclosure has provided several exemplary embodiments, one skilled in the art will recognize numerous variations, additions, and combinations to the embodiments disclosed herein, once informed by this disclosure. Such variations, additions, and combinations are within the contemplated scope of this disclosure and within are intended to be encompassed by the claims appended hereto.

One general aspect of embodiments disclosed herein includes a method of forming a package device, the method including: forming a bottom die, the bottom die including bottom contact pads embedded within and having respective top surfaces level with a bottom dielectric bonding layer. The method also includes forming a first top die by: forming a transistor structure on a bulk semiconductor substrate, forming a top interconnect structure on a top surface of the transistor structure. The method also includes bonding the top interconnect structure to a first support substrate, removing the bulk semiconductor substrate from the transistor structure. The method also includes forming a bottom interconnect structure on a bottom surface of the transistor structure. The method also includes and directly bonding one of the top interconnect structure and the bottom interconnect structure onto the bottom die.

Another general aspect of embodiments disclosed herein includes a method of forming a package device, including forming a first top die by forming a transistor layer containing transistors in a front surface of a bulk substrate. The method also includes forming a first interconnect structure on a front surface of the transistor layer by depositing on the front surface of the bulk substrate a stack conductive layers embedded within respective layers of a stack of deposited dielectric layers. The method also includes bonding a first support substrate to a top surface of the first interconnect structure. The method also includes thinning back a bottom surface of the bulk substrate to remove the bulk substrate from the transistor layer. The method also includes forming a second interconnect structure on a second surface of the transistor layer, opposite the front surface of the transistor layer. The method also includes forming a first bonding layer on a top surface of a structure selected from the group may include of the first interconnect structure, the second interconnect structure, and both the first and the second interconnect structure, the first bonding layer including first bonding pads embedded within a first bonding dielectric layer. The method also includes positioning the first top die over a bottom die having a bottom bonding layer including second bonding pads embedded within a second bonding dielectric layer. The method also includes aligning respective first bonding pads to respective second bonding pads. The method also includes and fusion bonding the first bonding layer to the second bonding layer and metal-to-metal bonding respective first bonding pads to respective second bonding pads. The method also includes positioning a second top die over the bottom die and adjacent the first top die, the second top die having third bonding pads embedded within a third bonding dielectric layer. The method also includes and fusion bonding the third bonding layer to the second bonding layer and metal-to-metal bonding respective third bonding pads to respective second bonding pads.

In one general aspect, a method may include forming a transistor in a wafer, the transistor being on a front side of the wafer. The method may also include forming a front side interconnect structure on the front side of the wafer, the front side interconnect structure including front side transistor contact that directly contacts a front side of the transistor. The method may furthermore include attaching a support substrate to the front side interconnect structure at a front side of the front side interconnect structure facing away from the wafer. The method may in addition include removing the wafer to expose a back side of the transistor, the back side of the wafer being opposite the front side of the wafer. The method may moreover include forming a back side interconnect structure on the back side of the transistor, the back side interconnect structure including a back side transistor contact that directly contacts the back side of the transistor. The method may also include directly bonding one of the front side interconnect structure or the back side interconnect structure to a bottom die.

In one general aspect, a method may include provisioning a top device by forming a transistor within a substrate, the transistor including a gate structure having a first topmost surface and a first source/drain having a second topmost surface and a first bottommost surface, and a second source/drain having a third topmost surface and a second bottommost surface, the first and the second bottommost surface being embedded within the substrate, forming a front side interconnect structure on a front side of the substrate, the front side interconnect structure including a gate contact that directly contacts the first topmost surface of the gate structure and a first source/drain contact that directly contacts the first bottommost surface of the first source/drain. The method may further include attaching a support substrate to the front side interconnect structure, removing the substrate to expose the first bottommost surface of the first source/drain and the second bottommost surface of the second source/drain, and forming a back side interconnect structure, the back side interconnect structure including a second source/drain contact that directly contacts the second bottommost surface of the second source/drain. The method may furthermore include directly bonding the top device to a bottom device through fusion bonding and through metal-to-metal bonding.

In one general aspect, a package device may include a bottom device having a first insulating bonding layer and first bonding pads; a first top device including: a first transistor having a gate, a first source/drain and a second source/drain, a first interconnect structure on a first side of the first transistor and including a first transistor contact directly contacting the gate and a second transistor contact directly contacting the first source/drain, and a second interconnect structure on a second side of the first transistor and including a third transistor contact directly contacting the second source/drain and a power rail directly contacting the third transistor contact. The package device may further include a first bond interface between the bottom device and the first top device, the first bond interface including a fusion bond between a bonding dielectric layer of the first top device and the first insulating bonding layer of the bottom device a metal-to-metal bond between a contact pad of the first top device and an one of the first bonding pads of the bottom device; and a second top device including: a substrate having a second transistor formed at least partially therein, and a third interconnect structure on a front side of the substrate, the third interconnect structure being bonded to the bottom device.

Yet another general aspect of embodiments disclosed herein includes a package device including a bottom substrate having a first insulating bonding layer and first bonding pads having respective top surfaces co-planar with a top surface of the first insulating bonding layer. The package device also includes a first integrated circuit having a device layer that includes a first transistor, a first interconnect structure on a first side of the device layer, and a second interconnect structure on a second side of the device layer. The second interconnect structure includes a power rail, where one of the first interconnect structure and the second interconnect structure includes a second insulating bonding layer forming a fusion bond interface with the first insulating bonding layer, and second bonding pads, respective ones of the second bonding pads forming metal-to-metal bonding interfaces with respective ones of the first bonding pads. In some embodiments, other one of the first interconnect structure and the second interconnect structure is bonded to a carrier substrate. The device also includes a second integrated circuit including: a substrate having a second transistor formed at least partially therein; and a third interconnect structure on a front side of the substrate, the third interconnect structure being bonded to the bottom substrate.

What is claimed is:

1. A method comprising:
forming a transistor in a wafer, the transistor being on a front side of the wafer;
forming a front side interconnect structure on the front side of the wafer, the front side interconnect structure including front side transistor contact that directly contacts a front side of the transistor;
attaching a support substrate to the front side interconnect structure at a front side of the front side interconnect structure facing away from the wafer;
removing the wafer to expose a back side of the transistor, the back side of the wafer being opposite the front side of the wafer;
forming a back side interconnect structure on the back side of the transistor, the back side interconnect structure including a back side transistor contact that directly contacts the back side of the transistor; and
directly bonding one of the front side interconnect structure or the back side interconnect structure to a bottom die.

2. The method of claim 1, wherein the one of the front side interconnect structure or the back side interconnect structure is the back side interconnect structure and further comprising:
forming on a surface of the back side interconnect structure a bonding dielectric layer and a metal contact pad embedded therein; and
fusion bonding the bonding dielectric layer to a second bonding dielectric layer on the bottom die and metal-to-metal bonding the metal contact pad to a second metal contact pad on the bottom die.

3. The method of claim 1, wherein the one of the front side interconnect structure or the back side interconnect structure is the front side interconnect structure and further comprising:
attaching a second support substrate to the back side interconnect structure at a back side of the back side interconnect structure facing away from the front side interconnect structure;
removing the support substrate from the front side interconnect structure;
forming on a surface of the front side interconnect structure a bonding dielectric layer and a metal contact pad embedded therein; and
fusion bonding the bonding dielectric layer to a second bonding dielectric layer on the bottom die and metal-to-metal bonding the metal contact pad to a second metal contact pad on the bottom die.

4. The method of claim 3, wherein the step of forming on the surface of the front side interconnect structure the bonding dielectric layer and the metal contact pad embedded therein is performed before the step of attaching a support substrate to the front side interconnect structure .

5. The method of claim 1, wherein the step of forming the transistor in the wafer comprises:
forming a stack of channel regions;
forming a gate structure surrounding channel regions of the stack; and
forming source/drain regions adjacent the channel regions.

6. The method of claim 5, wherein the front side transistor contact is formed directly on the gate structure, and wherein the back side transistor contact is formed directly on one of the source/drain regions.

7. The method of claim 1, wherein the step of forming a back side interconnect structure includes forming a power rail in direct contact with the back side transistor contact, the power rail configured to provide power to the transistor.

8. The method of claim 3, further comprising patterning the second support substrate to allow electrical connection to a power rail formed in the back side interconnect structure.

9. A method comprising:
provisioning a top device by:
forming a transistor within a substrate, the transistor including a gate structure having a first topmost surface and a first source/drain having a second topmost surface and a first bottommost surface, and a second source/drain having a third topmost surface and a second bottommost surface, the first and the second bottommost surface being embedded within the substrate,
forming a front side interconnect structure on a front side of the substrate, the front side interconnect structure including a gate contact that directly contacts the first topmost surface of the gate structure and a first source/drain contact that directly contacts the first bottommost surface of the first source/drain,
attaching a support substrate to the front side interconnect structure,
removing the substrate to expose the first bottommost surface of the first source/drain and the second bottommost surface of the second source/drain, and
forming a back side interconnect structure, the back side interconnect structure including a second source/drain contact that directly contacts the second bottommost surface of the second source/drain; and
directly bonding the top device to a bottom device through fusion bonding and through metal-to-metal bonding.

10. The method of claim 9, wherein the step of removing the substrate includes a process selected from the group consisting of grinding, etching, and combinations thereof.

11. The method of claim 9, further comprising:
attaching a second support substrate to the back side interconnect structure;
removing the support substrate; and
wherein the step of directly bonding the top device to the bottom device includes fusion bonding a bonding dielectric layer on the front side interconnect structure to a bottom dielectric layer on the bottom device and metal-to-metal bonding a contact pad embedded in the bonding dielectric layer to a bottom contact pad on the bottom device.

12. The method of claim 11, further comprising removing the second support substrate after the step of directly bonding the top device to the bottom device.

13. The method of claim 9, wherein the the back side interconnect structure further includes a power rail configured to deliver power to the transistor, the power rail being in direct contact with the first source/drain.

14. The method of claim 9, further comprising directly bonding a second device to the bottom device through fusion bonding and through metal-to-metal bonding and encapsulating the top device and the second device in an encapsulant.

15. The method of claim 14, further comprising a lid over the encapsulant.

16. The method of claim 14, further comprising a dummy device on the bottom device, the dummy device configured to provide increased topography uniformity relative to the topography in the absence of the dummy device.

17. A package device comprising:
a bottom device having a first insulating bonding layer and first bonding pads;
a first top device including:
a first transistor having a gate, a first source/drain and a second source/drain,
a first interconnect structure on a first side of the first transistor and including a first transistor contact directly contacting the gate and a second transistor contact directly contacting the first source/drain, and
a second interconnect structure on a second side of the first transistor and including a third transistor contact directly contacting the second source/drain and a power rail directly contacting the third transistor contact;
a first bond interface between the bottom device and the first top device, the first bond interface including a fusion bond between a bonding dielectric layer of the first top device and the first insulating bonding layer of the bottom device a metal-to-metal bond between a contact pad of the first top device and a one of the first bonding pads of the bottom device; and
a second top device including:
a substrate having a second transistor formed at least partially therein, and
a third interconnect structure on a front side of the substrate, the third interconnect structure being bonded to the bottom device.

18. The package device of claim 17, wherein the bonding dielectric layer of the first top device is on the first interconnect structure.

19. The package device of claim 17, wherein the bonding dielectric layer of the first top device is on the second interconnect structure.

20. The package device of claim 17, wherein the first top device includes a plurality of contact pads spaced apart by a first pitch, and the second top device is bonded to the bottom device through a second plurality of contact pads spaced apart by a second pitch different than the first pitch.
